(19) United States
(12) Patent Application Publication
(10) Pub. No.: US 2016/0118617 A1
(43) Pub. Date: Apr. 28, 2016

(54) ORGANIC EL ELEMENT

(71) Applicants: PIONEER CORPORATION, Kawasaki-shi, Kanagawa (JP); TOHOKU PIONEER CORPORATION, Tendo-shi, Yamagata (JP)

(72) Inventors: Yuji SAITO, Yonezawa-shi, Yamagata (JP); Hiroshi ABIKO, Yonezawa-shi, Yamagata (JP); Hiroki TAN, Yonezawa-shi, Yamagata (JP); Teruichi WATANABE, Yonezawa-shi, Yamagata (JP); Kunihiko SHIRAHATA, Yonezawa-shi, Yamagata (JP)

(73) Assignees: PIONEER CORPORATION, Kawasaki-shi, Kanagawa (JP); TOHOKU PIONEER CORPORATION, Tendo-shi, Yamagata (JP)

(21) Appl. No.: 14/891,745

(22) PCT Filed: Nov. 18, 2013
(86) PCT No.: PCT/JP2013/081069

§ 371 Date: Nov. 17, 2015

(30) Foreign Application Priority Data
May 17, 2013 (JP) 2013-105629

(51) Int. Cl. H01L 51/52; H01L 51/00; H01L 51/50

(52) U.S. Cl. CPC H01L 51/5246; H01L 51/5012; H01L 51/524; H01L 51/0097; H01L 51/5072; H01L 51/5092; H01L 2251/303; H01L 2251/5338; H01L 2251/558

(57) ABSTRACT

An organic EL element (10) includes a first electrode (110), an organic layer (120), and a second electrode (130). The organic layer (120) is located between the first electrode (110) and the second electrode (130). The second electrode (130) includes Ga in the vicinity of an interface with the organic layer (120). The second electrode (130) includes, for example, a Ga-containing layer (132) and a conductive layer (134). In the Ga-containing layer (132), an element having a highest content rate is Ga. The Ga-containing layer (132) is, for example, a thin Ga layer.

### TECHNICAL FIELD

The present invention relates to an organic EL element.

### BACKGROUND ART

There is an organic electroluminescence (EL) element as one of light sources for an illumination device or a display. The organic EL element has, for example, an organic layer provided between an anode (hole injection electrode) and a cathode (electron injection electrode). A technique relating to the organic EL element is disclosed in, for example, Patent Document 1 and Patent Document 2.

Patent Document 1 discloses that Ga is used as a cathode. In addition, Patent Document 2 discloses that a Ga-based metal and an alkali metal or an alkali-earth metal are contained in a cathode.

### RELATED DOCUMENTS

### Patent Documents

[Patent Document 1] Japanese Unexamined Patent Application Publication No. 2006-48946

[Patent Document 2] Japanese Unexamined Patent Application Publication No. 2006-144112

### SUMMARY OF THE INVENTION

### Technical Problem

Since an organic EL element such as an organic EL element includes an organic layer, a sealing structure is required therefor. However, a sealing structure incurs costs. Consequently, the inventors have examined that the structure of an organic EL element is devised in order to simplify a sealing structure using a liquid-state metal which has an electron injection capability and is chemically stabilized as in gallium (Ga).

The invention that solves this problem includes an example in which a sealing structure is simplified in an organic EL element.

### Solution to Problem

According to the invention of claim 1, there is provided an organic EL element including: a substrate; a first electrode; a second electrode; and an organic layer which is located between the first electrode and the second electrode, wherein the second electrode, the organic layer, and the first electrode are laminated in this order on one surface side of the substrate, and a Ga-containing region is included between the second electrode and the organic layer.

### BRIEF DESCRIPTION OF THE DRAWINGS

The above-mentioned objects, other objects, features and advantages will be made clearer from the preferred embodiment described below, and the following accompanying drawings.

FIG. 1 is a diagram illustrating a configuration of an organic EL element according to an embodiment.

FIG. 2 is a diagram illustrating an example of a configuration of an organic layer.

FIGS. 3 are diagrams illustrating a concentration distribution in depth directions of carbon, Ga, and a conductive material constituting a conductive layer at an interface between the organic layer and a second electrode.

FIG. 4 is a diagram illustrating a configuration of an organic EL element according to Example 1.

FIG. 5 is a diagram illustrating a configuration of an organic EL element according to Example 2.

FIG. 6 is a diagram illustrating a configuration of an organic EL element according to Example 3.

FIG. 7 is a diagram illustrating a configuration of an organic EL element according to Example 4.

FIG. 8 is a diagram illustrating a configuration of an organic EL element according to Example 5.

FIG. 9 is a diagram illustrating a configuration of an organic EL element according to Example 6.

FIG. 10 is a diagram illustrating a configuration of an organic EL element according to a comparative example.

FIG. 11 is a diagram illustrating changes of light-emitting areas of samples according to Example 6 and the comparative example.

FIG. 12 is a diagram illustrating a configuration of an organic EL element according to Example 7.

FIG. 13 is a diagram illustrating changes of the light-emitting areas of samples according to Example 7 and the comparative example.

### DESCRIPTION OF EMBODIMENTS

Hereinafter, an embodiment of the present invention will be described with reference to the accompanying drawings. In all the drawings, like elements are referenced by like reference numerals and the descriptions thereof will not be repeated.

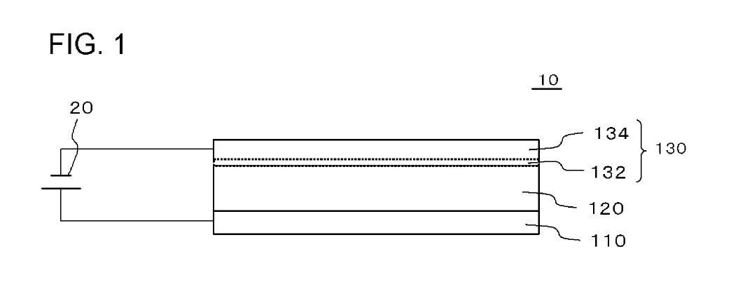

FIG. 1 is a diagram illustrating a configuration of an organic EL element 10 according to an embodiment. The organic EL element 10 according to the present embodiment includes a first electrode 110, an organic layer 120, and a second electrode 130. The organic layer 120 is located between the first electrode 110 and the second electrode 130. The second electrode 130 includes Ga at an interface with the organic layer 120. In the example shown in the drawing, the second electrode 130 includes a Ga-containing layer 132 (Ga-containing region) and a conductive layer 134. In the Ga-containing layer 132, an element having a highest content rate is Ga. The Ga-containing layer 132 is, for example, a thin Ga layer having a thickness of approximately 0.5 to 50 nm. However, a boundary between the Ga-containing layer 132 and the organic layer 120 may not be clearly present. Similarly, a boundary between the Ga-containing layer 132 and the conductive layer 134 may not be clearly present. In addition, the thickness of the Ga-containing layer 132 may be configured such that several Ga atoms are laminated. The Ga concentration of the Ga-containing layer 132 increases from the organic layer 120 side, is set to a peak between the organic layer 120 and the second electrode 130, and then decreases toward the second electrode 130 side. The organic EL element 10 is, for example, an organic EL element, but may be other organic EL elements. In addition, when the organic EL element 10 is an organic EL element, the organic EL element 10 can be used as a light source of an illumination device, or a display device.

The first electrode 110 functions as an anode, and at least the conductive layer 134 out of the second electrode 130 functions as a cathode. One of the first electrode 110 and the conductive layer 134 is a transparent electrode having optical transparency. A material of the transparent electrode includes, for example, an inorganic material such as an indium tin oxide (ITO) or an indium zinc oxide (IZO), or a conductive polymer such as a polythiophene derivative.

In addition, the other of the first electrode 110 and the conductive layer 134 includes a metal layer made of a metal selected from a first group consisting of Au, Ag, Pt, Sn, Zn, and In, or an alloy of metals selected from this first group.

The organic layer 120 includes a light-emitting layer. A voltage is applied between the first electrode 110 and the second electrode 130 from a power supply 20, and thus the organic layer 120 emits light. This emission light is emitted to the outside from an electrode out of the first electrode 110 and the conductive layer 134 which serves as a transparent electrode.

The first electrode 110, the Ga-containing layer 132, and the conductive layer 134 are formed using, for example, a vapor deposition method. The organic layer 120 is formed using a vapor deposition method or the coating method. As a coating method, for example, spray coating, dispenser coating, ink jet, or printing may be used. Meanwhile, when the organic layer 120 is formed by a plurality of layers, each of these layers may be formed using the same method, and at least one layer may be formed using a separate method from those of the rest. When the layers are formed using a coating method, examples of coating materials to be used for forming the organic layer 120 may include a polyalkylthiophene derivative, a polyaniline derivative, triphenylamine, a sol-gel film of an inorganic compound, an organic compound film containing a Lewis acid, and a conductive polymer. However, a material constituting the organic layer 120 is not limited thereto.

Meanwhile, the first electrode 110, the organic layer 120, and the second electrode 130 are formed using a substrate. The substrate may be formed of, for example, an inorganic material such as glass, and may be formed of an organic material such as a resin. The substrate may have flexibility. In this case, the thickness of the substrate is, for example, equal to or greater than 10 pm and equal to or less than 1,000 μm. Even in this case, the substrate may be formed of any of an inorganic material and an organic material. In addition, in a thickness direction, the first electrode 110 maybe located closer to the substrate than the second electrode 130, and the second electrode 130 may be located closer to the substrate than the first electrode 110. In the latter case, even when a substrate using a resin material is used, it is possible to prevent the organic layer 120 from being deteriorated due to moisture having passed through the substrate.

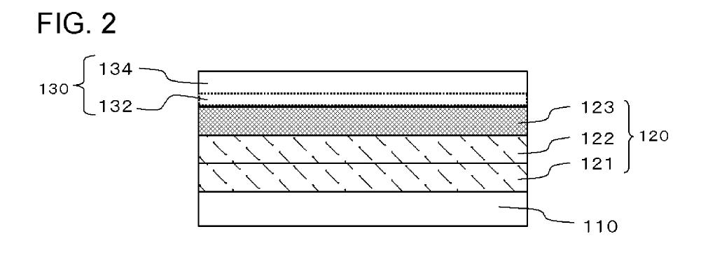

FIG. 2 is a diagram illustrating an example of a configuration of the organic layer 120. In the example shown in the drawing, the organic layer 120 includes a hole injection layer 121, a hole transport layer 122, and a light-emitting layer 123, in order from the side close to the first electrode 110. The Ga-containing layer 132 comes into contact with the light-emitting layer 123. That is, in the present embodiment, the Ga-containing layer 132 functions as an electron injection layer (and an electron transport layer). The hole injection layer 121 and the hole transport layer 122 may be constituted by one organic layer. Meanwhile, an organic material constituting the hole injection layer 121, an organic material constituting the hole transport layer 122, and an organic material constituting the light-emitting layer 123 are not particularly limited, and general materials can be used as these organic materials. The hole injection layer 121 may include a molybdenum oxide (MoO₃). Meanwhile, the organic layer 120 may include at least one of an electron injection layer and an electron transport layer separately from the Ga-containing layer 132.

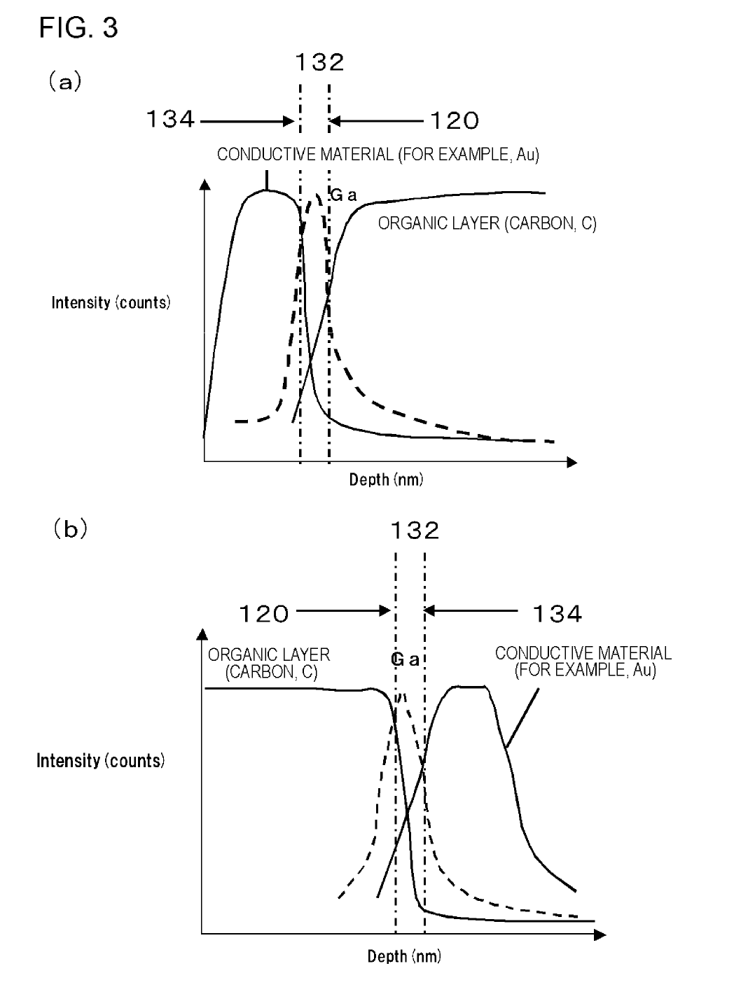

FIG. 3(a) is a diagram illustrating a concentration distribution in depth directions of carbon, Ga, and a conductive material constituting the conductive layer 134 at an interface between the organic layer 120 and the second electrode 130. In the example shown in the drawing, the first electrode 110, the organic layer 120, the Ga-containing layer 132, and the conductive layer 134 are laminated in order from the substrate side. FIG. 3(b) is a diagram illustrating a concentration distribution when the conductive layer 134, the Ga-containing layer 132, the organic layer 120, and the first electrode 110 are laminated in order from the substrate side. In this case, as shown in FIG. 3(b), the right and left are reversed to those in FIG. 3(a).

As shown in these drawings, at an interface between the organic layer 120 and the Ga-containing layer 132, the concentration of carbon lowers drastically toward (or into) the Ga-containing layer 132, and the concentration of Ga rises drastically instead. In the Ga-containing layer 132, the amount of Ga becomes largest. At an interface between the Ga-containing layer 132 and the conductive layer 134, the concentration of Ga lowers drastically toward the conductive layer 134, but the concentration of a conductive material constituting the conductive layer 134 rises drastically instead thereof. Meanwhile, such an analysis can be performed using, for example, a time-of-flight secondary ion mass spectrometer (TOF-SIMS).

According to the present embodiment, Ga is included at an interface between the organic layer 120 and the second electrode 130. Therefore, this layer containing Ga (Ga-containing layer 132) can be used as an electron injection layer. Therefore, as compared to a case where an electron injection layer made of a commonly used alkali metal compound or the like is used, for example, even when deterioration factors such as moisture or oxygen infiltrate into an interface between the second electrode 130 and the organic layer 120, it is possible to reduce a deterioration in the light-emission characteristics of the organic layer 120 due to these deterioration factors. Therefore, it is possible to simplify the sealing structure of the organic EL element 10. Meanwhile, even when an electron transport layer is provided between the Ga-containing layer 132 and the light-emitting layer 123, it is possible to reduce a deterioration in the light-emission characteristics of the organic layer 120. In addition, Ga is a liquid at ordinary temperature, and has high flowability. Therefore, the Ga-containing layer 132 is provided, and thus it is also possible to improve adhesion between the second electrode 130 and the organic layer 120.

### EXAMPLES

### Example 1

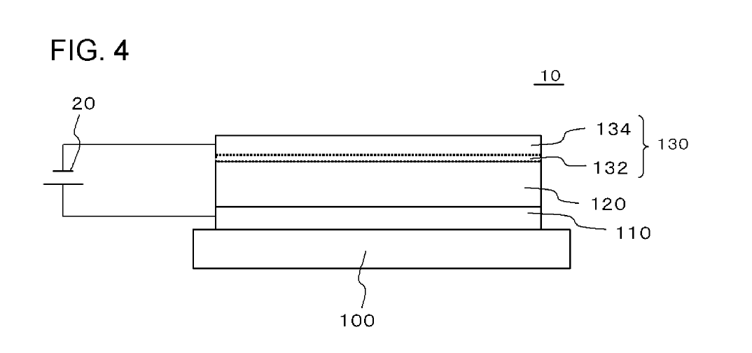

FIG. 4 is a diagram illustrating a configuration of an organic EL element 10 according to Example 1. The organic EL element 10 according to the present example has a configuration in which the first electrode 110, the organic layer 120, and the second electrode 130 are laminated in this order on the substrate 100. In the present example, light from the organic layer 120 is extracted from the substrate 100 side.

The substrate 100 is, for example, a transparent substrate. In the present example, the substrate 100 may be a glass substrate. Thereby, it is possible to inexpensively manufacture the organic EL element 10 excellent in heat resistance or the like.

The substrate 100 may be a film-shaped substrate constituted by a resin material. In this case, it is possible to realize a display having particularly high flexibility. A resin material constituting a film-shaped substrate is, for example, polyethylene terephthalate, polyethylene naphthalate or polycarbonate.

The first electrode 110 is a transparent electrode. The conductive layer 134 includes a metal layer made of a metal selected from a first group consisting of Au, Ag, Pt, Sn, Zn, and In, or an alloy of metals selected from this first group.

Next, a method of manufacturing the organic EL element 10 according to the present example will be described. First, the first electrode 110 is formed on the substrate 100 using, for example, a vapor deposition method. Next, the organic layer 120 is formed using a vapor deposition method or a coating method. Next, the Ga-containing layer 132 is formed using, for example, a vapor deposition method, and then the conductive layer 134 is formed using, for example, a vapor deposition method.

In the present example, the Ga-containing layer 132 can also be used as an electron injection layer. Therefore, as compared to a case where an electron injection layer made of a commonly used alkali metal compound or the like is used, even when moisture or oxygen infiltrates into the organic layer 120, it is possible to prevent the light-emission characteristics of the organic layer 120 from being deteriorated due to the moisture or oxygen. Therefore, it is possible to simplify the sealing structure of the organic EL element 10. When the organic EL element 10 is used as one light-emitting unit in an electronic device, it is possible to prevent the light-emitting area of the light-emitting unit from decreasing (shrinking).

Meanwhile, in the present example, a material constituting the first electrode 110 and a material constituting the conductive layer 134 may be reversed. In this case, light emitted from the organic layer 120 may be designed so as to be emitted from the second electrode 130 side.

### Example 2

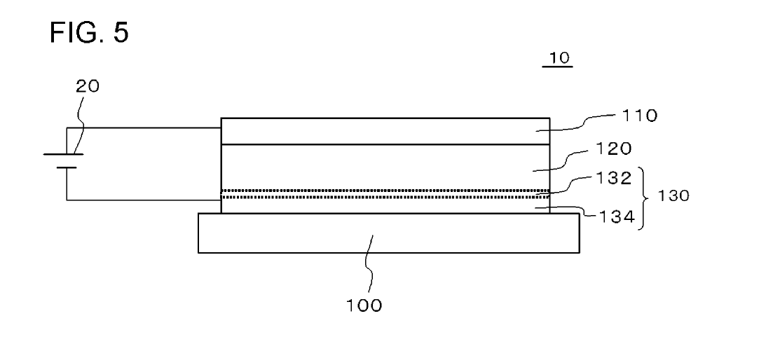

FIG. 5 is a diagram illustrating a configuration of an organic EL element 10 according to Example 2. The organic EL element 10 according to the present example has a configuration in which the second electrode 130, the organic layer 120, and the first electrode 110 are laminated in this order on the substrate 100. In the present example, light from the organic layer 120 is extracted from the substrate 100 side as well.

The configuration of the substrate 100 is the same as that in Example 1. The conductive layer 134 is a transparent electrode. The first electrode 110 includes a metal layer made of a metal selected from a first group consisting of Au, Ag, Pt, Sn, Zn, and In, or an alloy of metals selected from this first group.

Next, a method of manufacturing the organic EL element 10 according to the present example will be described. First, the conductive layer 134 is formed on the substrate 100 using, for example, a vapor deposition method. Next, the Ga-containing layer 132 is formed using, for example, a vapor deposition method. Next, the organic layer 120 is formed using a vapor deposition method or a vapor deposition method. Thereafter, the first electrode 110 is formed using, for example, a vapor deposition method.

In the present example, similarly to Example 1, as compared to a case where an electron injection layer constituted by an organic material is used, even when moisture or oxygen infiltrates into the organic layer 120, it is possible to prevent the light-emission characteristics of the organic layer 120 from being deteriorated due to the moisture or oxygen. Therefore, it is possible to simplify the sealing structure of the organic EL element 10.

Meanwhile, in the present example, a material constituting the first electrode 110 and a material constituting the conductive layer 134 may be reversed. In this case, light emitted from the organic layer 120 may be designed so as to be emitted from the second electrode 130 side.

### Example 3

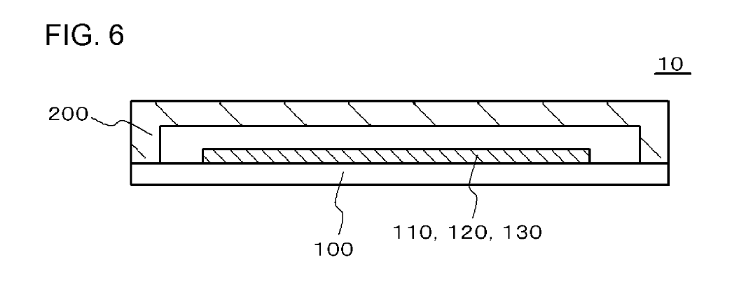

FIG. 6 is a diagram illustrating a configuration of an organic EL element 10 according to Example 3. The organic EL element 10 according to the present example is configured such that a laminated body of the first electrode 110, the organic layer 120, and the second electrode 130 is formed on one surface of the substrate 100, and that the one surface is sealed by a sealing member 200. The sealing member 200 is formed of, for example, glass. However, a drying agent is not included in the inside of the sealing member 200. The lamination order of the first electrode 110, the organic layer 120, and the second electrode 130 may be the same as that in Example 1, and may be the same as that in Example 2.

According to the present example, a drying agent is not included in the inside of the sealing member 200. Therefore, it is possible to simplify the sealing structure of the organic EL element 10. In addition, as is the case with Example 1, even when moisture or oxygen infiltrates into the organic layer 120, it is possible to prevent the light-emission characteristics of the organic layer 120 from being deteriorated due to the moisture or oxygen.

In addition, regarding an adhesive enabling adhesion between the substrate 100 and the sealing substrate 200, an inexpensive adhesive having low sealing properties can be selected, and an effect of extending a product design range is also exhibited. It is possible to allow adoption in a flexible electronic device in which the organic EL element 10 can be used as a display unit, and an effect of suppressing a reduction in a light-emitting area, improving the degree of freedom of design, or the like is exhibited.

### Example 4

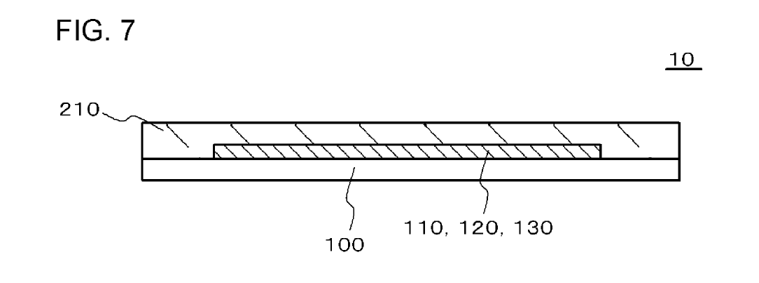

FIG. 7 is a diagram illustrating a configuration of an organic EL element 10 according to Example 4. The organic EL element 10 according to the present example is configured such that a laminated body of the first electrode 110, the organic layer 120, and the second electrode 130 are formed on one surface of the substrate 100, and that the one surface is sealed by a sealing resin 210. The sealing resin 210 is, for example, an epoxy resin.

According to the present example, the organic EL element 10 is sealed by the sealing resin 210. Therefore, as compared to a case where the sealing member 200 is used, the sealing structure of the organic EL element 10 is further simplified. In addition, an example in the present example is effective in a configuration in which a high sealing technique is required, for example, when a flexible material is used in the substrate 100.

### Example 5

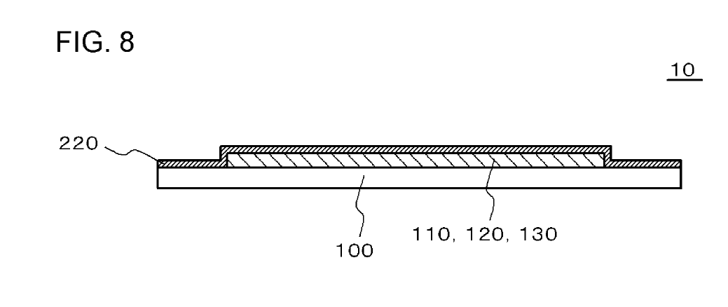

FIG. 8 is a diagram illustrating a configuration of an organic EL element 10 according to Example 5. The organic EL element 10 according to the present example is configured such that a laminated body of the first electrode 110, the organic layer 120, and the second electrode 130 are formed on one surface of the substrate 100, and that the one surface is sealed by a protective film 220.

The protective film 220 includes at least a film constituted by an oxide, for example, a film constituted by an aluminum oxide. The film thickness of the protective film 220 is, for example, equal to or greater than 10 nm and equal to or less than 30 nm. The protective film 220 may have a single-layered structure, and may have a structure in which a plurality of metal oxide films are laminated. The protective film 220 is formed using, for example, an atomic layer deposition (ALD) method.

According to the present example, the organic EL element 10 is sealed by the protective film 220. Therefore, as compared to a case where the sealing member 200 is used, the sealing structure of the organic EL element 10 is further simplified. Meanwhile, the sealing resin 210 shown in FIG. 7 may be further provided on the sealing member 200. This allows the sealability of the organic EL element 10 to be further increased.

### Example 6

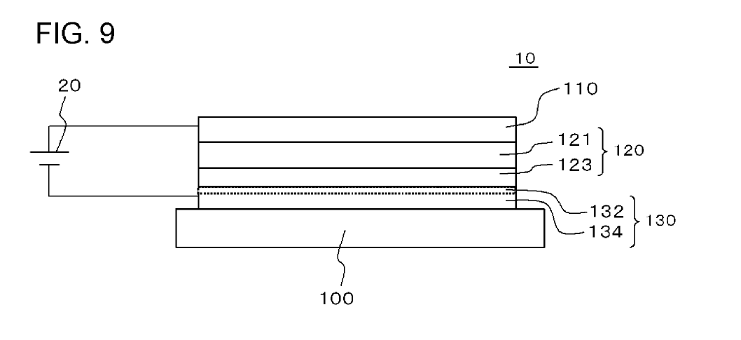

An organic EL element 10 having a structure shown in FIG. 9 was created (Sample 1). A glass substrate was used as the substrate 100. The second electrode 130, the organic layer 120, and the first electrode 110 were formed in this order on the substrate 100. The conductive layer 134 of the second electrode 130 is formed of an indium tin oxide (ITO) having a thickness of 155 nm. In addition, the Ga-containing layer 132 was formed on the conductive layer 134. A Ga layer having a thickness of 1 nm was used as the Ga-containing layer 132. The Ga-containing layer 132 also serves as an electron injection layer. In addition, a multi-layered structure in which the light-emitting layer 123 and the hole injection layer 121 were laminated in this order was used for the organic layer 120. In addition, aluminato-tris-8-hydroxyquinolate (Alq) having a thickness of 50 nm was used as the light-emitting layer 123, and a molybdenum oxide (MoO₃) having a thickness of 25 nm was used as the hole injection layer 121. Al having a thickness of 120 nm was used as the first electrode 110.

In addition, the organic EL element 10 having the same structure as that of Sample 1 except for the structure of the first electrode 110 was created. In Sample 2, Au having a thickness of 80 nm was used as the first electrode 110.

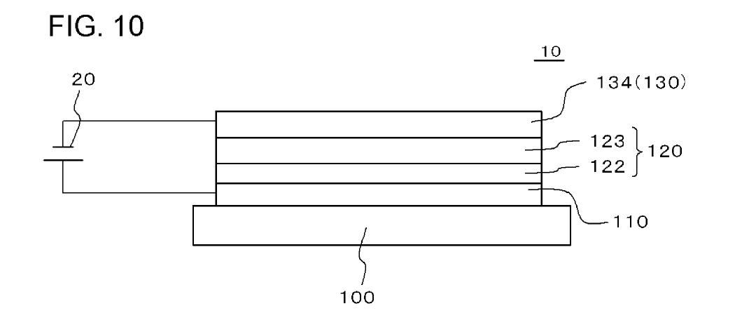

In addition, an organic EL element 10 having a structure shown in FIG. 10 was created (comparative example). The organic EL element 10 according to comparative example has a structure in which the first electrode 110, the organic layer 120, and the conductive layer 134 are laminated in this order on the substrate 100. ITO having a thickness of 155 nm was used as the first electrode 110, and Al having a thickness of 120 nm was used as the conductive layer 134. In addition, as the organic layer 120, the hole transport layer 122 and the light-emitting layer 123 were laminated in this order. N,N-di(naphthalene-1-yl)-N,N-diphenyl-benzidene (NPB) having a thickness of 50 nm was used as the hole transport layer 122, and aluminato-tris-8-hydroxyquinolate (Alq) having a thickness of 50 nm was used as the light-emitting layer 123.

Each of Samples 1 and 2 and the comparative example was driven in a non-sealed state, and how a light-emitting state changed with a light-emitting time was inspected.

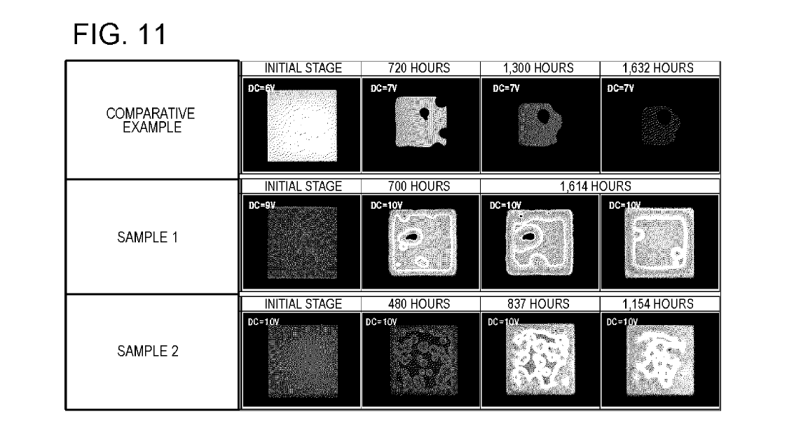

FIG. 11 is a photograph illustrating a relationship between a light-emitting area of each of Samples 1 and 2 and the comparative example and a light-emitting time.

In the comparative example, the light-emitting time exceeded 720 hours and then a non-light-emitting region was generated. This non-light-emitting region increased with an increase in the light-emitting time, and a light-emitting region was hardly present when the light-emitting time was extended to 1,632 hours. It is estimated that this is because the organic layer 120 is deteriorated due to moisture or oxygen.

On the other hand, regardless of Samples 1 and 2 not being sealed, there was no change in the light-emitting area even after the light-emitting time exceeded 1,000 hours. However, in both Samples 1 and 2, a linear region (a high-luminance region) having high luminance was generated in the light-emitting region. In addition, when the light-emitting time increased, the area of this high-luminance region was enlarged, and a current was reduced regardless of the same voltage being applied. It is estimated that this is because, as a result of the infiltration of moisture in at least one of the electron side and the hole side, the recombination of carriers is suppressed or the carriers are trapped.

### Example 7

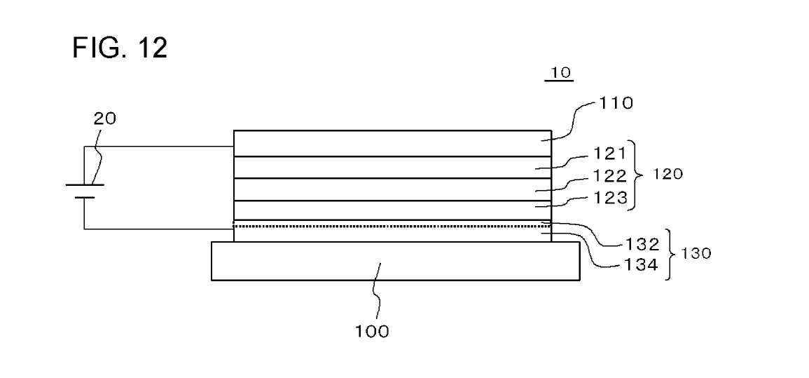

An organic EL element 10 having a structure shown in FIG. 12 was created. The organic EL element 10 has the same structure as that of Sample 1, except that the hole transport layer 122 is provided between the hole injection layer 121 and the light-emitting layer 123 of the organic layer 120. NPB having a thickness of 50 nm was used as the hole transport layer 122. Meanwhile, an Al layer having a thickness of 60 nm was used as the first electrode 110. In Sample 3, a continuous film formation from the second electrode 130 to the first electrode 110 was performed. In Sample 4, a continuous film formation from the second electrode 130 to the organic layer 120 was performed, and then a film formation of the first electrode 110 was performed thereon after exposure to the atmosphere for an hour. Meanwhile, none of Samples 3 and 4 include a sealing structure.

In addition, an organic EL element 10 having the same structure as that of Sample 3, except that an Au layer having a thickness of 80 nm was used as the first electrode 110, was created (Sample 5). Further, an organic EL element 10 having the same structure as that of Sample 4, except that an Au layer having a thickness of 80 nm was used as the first electrode 110, was created (Sample 6).

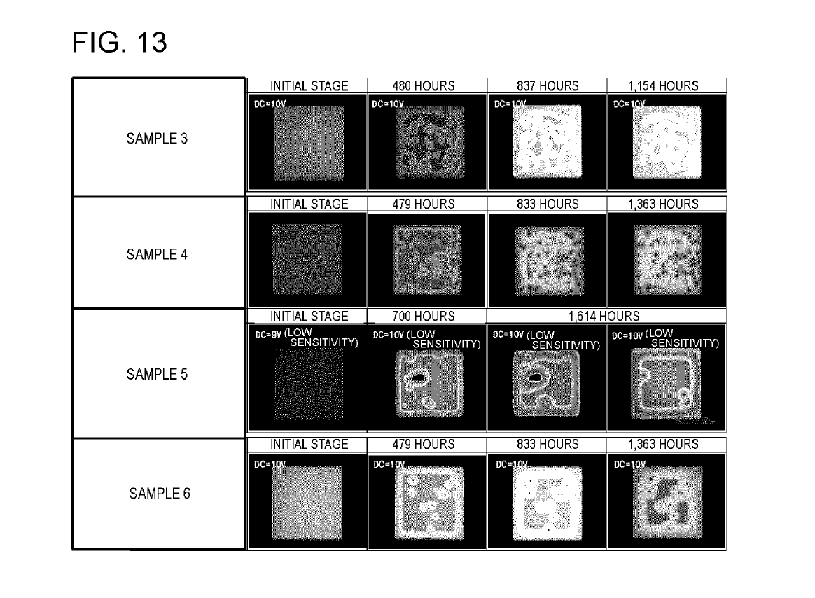

FIG. 13 is a photograph illustrating a relationship between a light-emitting area of each of samples 3 to 6 and a light-emitting time. In all of samples 3 to 6, a reduction in the light-emitting area was hardly seen even when the light-emitting time exceeded 1,000 hours. In addition, when samples 4 and 6 were compared to Samples 3 and 5, the generation of the high-luminance region described in Example 6 was suppressed. From this, when exposure to the atmosphere is performed after the organic layer 120 is formed and before the first electrode 110 is formed, it can be understood that the generation of the high-luminance region is suppressed.

As described above, although the embodiment and examples have been set forth with reference to the accompanying drawings, they are merely illustrative of the present invention, and various configurations other than those stated above may be adopted.

Meanwhile, according to the embodiment and the examples described above, the following invention is disclosed.

(Appendix 1)

An organic EL element including:

a first electrode;

a second electrode; and

an organic layer which is located between the first electrode and the second electrode,

wherein the second electrode comes into contact with the organic layer, and includes Ga at an interface with the organic layer.

(Appendix 2)

An organic EL element including:

a first electrode;

a second electrode;

an organic layer which is located between the first electrode and the second electrode; and

a Ga-containing layer which is located between the organic layer and the second electrode,

wherein in the Ga-containing layer, an element having a highest content rate is Ga.

(Appendix 3)

The organic EL element according to appendix 1 or 2, wherein the first electrode is an anode, and the second electrode is a cathode.

(Appendix 4)

The organic EL element according to appendix 3, further including a substrate

wherein the first electrode, the organic layer, and the second electrode are laminated in this order on one surface side of the substrate.

(Appendix 5)

The organic EL element according to appendix 4, wherein the organic layer includes a light-emitting layer,

the first electrode has a light-transmissive property, and

the second electrode includes a metal layer made of a metal selected from a first group consisting of Au, Ag, Pt, Sn, Zn, and In, or an alloy of metals selected from the first group.

(Appendix 6)

The organic EL element according to appendix 3, further including a substrate,

wherein the second electrode, the organic layer, and the first electrode are laminated in this order on one surface side of the substrate.

(Appendix 7)

The organic EL element according to appendix 6, wherein the organic layer includes a light-emitting layer,

the second electrode has a light-transmissive property, and

the first electrode includes a metal layer made of a metal selected from a first group consisting of Au, Ag, Pt, Sn, Zn, and In, or an alloy of metals selected from the first group.

(Appendix 8)

The organic EL element according to appendix 7, wherein a hole injection layer is included between the first electrode and the organic layer.

(Appendix 9)

The organic EL element according to appendix 8, wherein the hole injection layer includes a molybdenum oxide.

This application claims priority from Japanese Patent Application No. 2013-105629 filed on May 17, 2013, the content of which is incorporated herein by reference in its entirety.

1. An organic EL element comprising:
a substrate;
a first electrode;
a second electrode; and
an organic layer between the first electrode and the second electrode,
wherein the second electrode, the organic layer, and the first electrode are laminated in sequence from a surface side of the substrate, and
a Ga-containing region is between the second electrode and the organic layer.

2. The organic EL element according to claim 1, wherein Ga has a highest content rate in the Ga-containing region.

3. The organic EL element according to claim 2, wherein in the Ga-containing region, a peak of a concentration of the Ga is present between the organic layer and the second electrode.

4. The organic EL element according to claim 1, further comprising a molybdenum oxide included between the first electrode and the organic layer.

5. The organic EL element according to claim 1, further comprising a sealing member that seals the first electrode, the organic layer, the Ga-containing layer, and the second electrode, wherein a drying agent is not present in inside the sealing member.

6. The organic EL element according to claim 1, further comprising a sealing resin that seals the first electrode, the organic layer, the Ga-containing layer, and the second electrode, wherein a drying agent is not present in inside the sealing resin.

7. The organic EL element according to claim 6, wherein the substrate comprises a flexible substrate.

8. The organic EL element according to claim 1, wherein the organic EL element does not include any sealing member or sealing resin.

9. The organic EL element according to claim 1, wherein the Ga-containing region has a thickness of 0.5 to 50 nm.

10. An organic EL element comprising:
a substrate;
a first electrode and a second electrode on the substrate;
an organic layer between the first electrode and the second electrode; and
a Ga-containing region between the second electrode and the substrate,
light emitted from the organic layer is emitted from the first electrode side,
wherein ,in a depth direction of the organic EL element, a peak of a concentration of the Ga is present between a peak of a concentration of the material of the second electrode and a peak of a concentration of carbon.

11. The organic EL element according to claim 10, wherein a TOF-SIMS analysis is used to determine one or more of the peak of the concentration of the Ga, the peak of the concentration of the material of the second electrode, and the peak of the concentration of carbon in the depth direction.
